(19) United States
(12) Patent Application Publication
(10) Pub. No.: US 2019/0174659 A1
(43) Pub. Date: Jun. 6, 2019

(54) CIRUIT BOARD ASSEMBLY AND SHIELDING DEVICE

(71) Applicant: PEGATRON CORPORATION, Taipei City (TW)

(72) Inventors: Wen-Chi Lin, Taipei City (TW); Wei-Chun Tsao, Taipei City (TW); Yao-Chiang Yang, Taipei City (TW)

(73) Assignee: PEGATRON CORPORATION, TAIPEI CITY (TW)

(21) Appl. No.: 16/192,541

(22) Filed: Nov. 15, 2018

(30) Foreign Application Priority Data
Dec. 4, 2017 (TW) 106142436

(51) Int. Cl. H05K 9/00; H05K 7/20

(52) U.S. Cl. CPC H05K 9/0081; H05K 7/2039; H05K 9/0032

(57) ABSTRACT

A circuit board assembly includes a circuit board, a shielding frame, a chip, and a heat dissipating member. The shielding frame is fixed to and protrudes from the circuit board. The shielding frame includes a first encircled positioning portion away from the circuit board. The chip is disposed on the circuit board and is located in the shielding frame. The heat dissipating member is detachably disposed on the shielding frame, and includes a plate and a second encircled positioning portion disposed on the plate. When the heat dissipating member is disposed on the circuit board, the plate leans against the shielding frame and covers the chip, the second encircled positioning portion and the first encircled positioning portion correspond with each other in shape and position, so as to position the plate and the shielding frame. A shielding device is also disclosed.

### CROSS REFERENCE TO RELATED APPLICATION

This application claims the priority benefit of Taiwan application serial no. 106142436, filed on Dec. 4, 2017. The entirety of the above-mentioned patent application is hereby incorporated by reference herein and made a part of specification.

### BACKGROUND OF THE INVENTION

### 1. Field of the Invention

The present invention relates to a circuit board assembly and a shielding device, and particularly to a circuit board assembly and a shielding device that prevent electromagnetic interference.

### 2. Description of Related Art

Electromagnetic radiation and distribution of electromagnetic field generated during operations of electronic products and electrical equipment affect performance of other electronic devices, apparatus or elements. Such phenomenon is called electromagnetic interference (EMI). Due to increase of operational frequency of electronic devices and miniaturization of manufacturing process, the number of electronic components on the printed circuit board is highly increased, which causes serious electromagnetic interference and degrades the performance of the electronic devices. Hence, how to prevent electromagnetic interference in each electronic component during the operation is a significant issue.

### SUMMARY

The invention discloses electronic assemblies, which prevent electromagnetic interference via overlapped a heat dissipating member and a shielding frame.

The invention discloses a shielding frame adapted to be disposed on a circuit board for prevention of electromagnetic interference.

A circuit board assembly includes a circuit board, a shielding frame, a chip, and a heat dissipating member. The shielding frame is fixed to and protrudes from the circuit board. The shielding frame includes a first encircled positioning portion that is away from the circuit board. The chip is disposed on the circuit board and located in the shielding frame. The heat dissipating member is detachably disposed on the shielding frame, and includes a plate and a second encircled positioning portion that is disposed on the plate. When the heat dissipating member is disposed on the circuit board, the plate leans against the shielding frame and covers the chip, the second encircled positioning portion and the first encircled positioning portion correspond with each other in shape and position, so as to position the plate and the shielding frame.

According to an embodiment of the invention, the second encircled positioning portion is an encircled groove. The first encircled positioning portion is an encircled protrusion that corresponds to the encircled groove.

According to an embodiment of the invention, the first encircled positioning portion has a bent section in contact with a bottom wall of the encircled groove.

According to an embodiment of the invention, the shielding frame is electrically connected to a ground terminal of the circuit board.

According to an embodiment of the invention, the circuit board assembly further includes a plurality of fixing members. The heat dissipating member further includes a plurality of through holes that are formed at a surrounding of the second encircled positioning portion. The fixing members individually pass through the through holes, and are fixed to the circuit board and are electrically connected to a ground terminal of the circuit board.

A circuit board assembly includes a circuit board, a shielding frame, a chip, and a heat dissipating member. The shielding frame is fixed to and protrudes from the circuit board. The chip is disposed on the circuit board and is located in the shielding frame. The heat dissipating member is detachably disposed on the shielding frame. When the heat dissipating member is disposed on the circuit board, the heat dissipating member leans against the shielding frame and covers the chip, and the shielding frame overlaps the heat dissipating member at a junction in a radiation direction from a center of the chip.

A shielding device is adapted to be disposed on a circuit board and cover a chip that is disposed on the circuit board. The shielding device includes a shielding frame and a heat dissipating member. The shielding frame includes a first encircled positioning portion. The heat dissipating member includes a plate and a second encircled positioning portion that is disposed on the plate. The second encircled positioning portion and the first encircled positioning portion correspond with each other in shape and position, so as to position the plate and the shielding frame. When the shielding device is disposed on the circuit board, an encircled abutting section of the shielding frame connected to the first encircled positioning portion leans against the circuit board, and the shielding frame and the heat dissipating member cooperatively cover the chip.

According to an embodiment of the invention, the second encircled positioning portion is an encircled groove. The first encircled positioning portion is an encircled protrusion that corresponds to the encircled groove.

According to an embodiment of the invention, the first encircled positioning portion has a bent section in contact with a bottom wall of the encircled groove.

According to an embodiment of the invention, the plate has a first surface and a second surface opposite the first surface. The second encircled positioning portion is located at the first surface. The heat dissipating member further includes a plurality of fins located at the second surface.

Based on the above, when the heat dissipating member is disposed on the circuit board, the plate of the heat dissipating member leans against the shielding frame and covers the chip. One of the second encircled positioning portion and the first encircled positioning portion extends along a normal direction of the plate to another one of the second and first encircled positioning portions, so as to overlap each other. According to the present invention, the shielding frame and the plate of the heat dissipating member lean against each other and are used for covering the chip. Via integration of the plate and the shielding frame, transmission of electromagnetic radiation can be blocked to prevent influence of electromagnetic interference on operational performance of the chip.

In addition, according to the present invention, the shielding device includes the heat dissipating member and the shielding frame, and the plate of the heat dissipating member is configured as an upper cover of the shielding frame. That is, the shielding frame of the present invention is not required to have an additional upper cover, so as to reduce size of the shielding frame and reduce production cost.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is an exploded perspective view of a circuit board assembly according to an embodiment of the invention.

FIG. 1B is another exploded perspective view of the circuit board assembly of FIG. 1A.

FIG. 2A is an assembled side view of the circuit board assembly of FIG. 1A.

FIG. 2B is an exploded side view of the circuit board assembly of FIG. 1A.

FIG. 3A is a sectional view of the circuit board assembly of FIG. 1A.

FIG. 3B is a partial enlarged view of an area A1 in FIG. 3A.

FIGS. 3C and 3D are partial enlarged views of areas A2 and A3, respectively, which replace the area A1 in other embodiments.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In general, electromagnetic interference which is a common phenomenon exists in electronic devices. For example, there are many kinds of high-efficiency electronic components disposed on the computer motherboard, such as central processing unit (CPU), computer memory, southbridge chip, northbridge chip, and graphics processing unit, etc. During operations, the abovementioned electronic components generate electromagnetic fields and electromagnetic radiation that outwardly emit, which render disturbance between the electronic components, thus degrading operational performance thereof.

An embodiment according to the present invention is directed to a circuit board assembly, which prevents electromagnetic interference and is effectively reduced in size. The detail description is recited as follows.

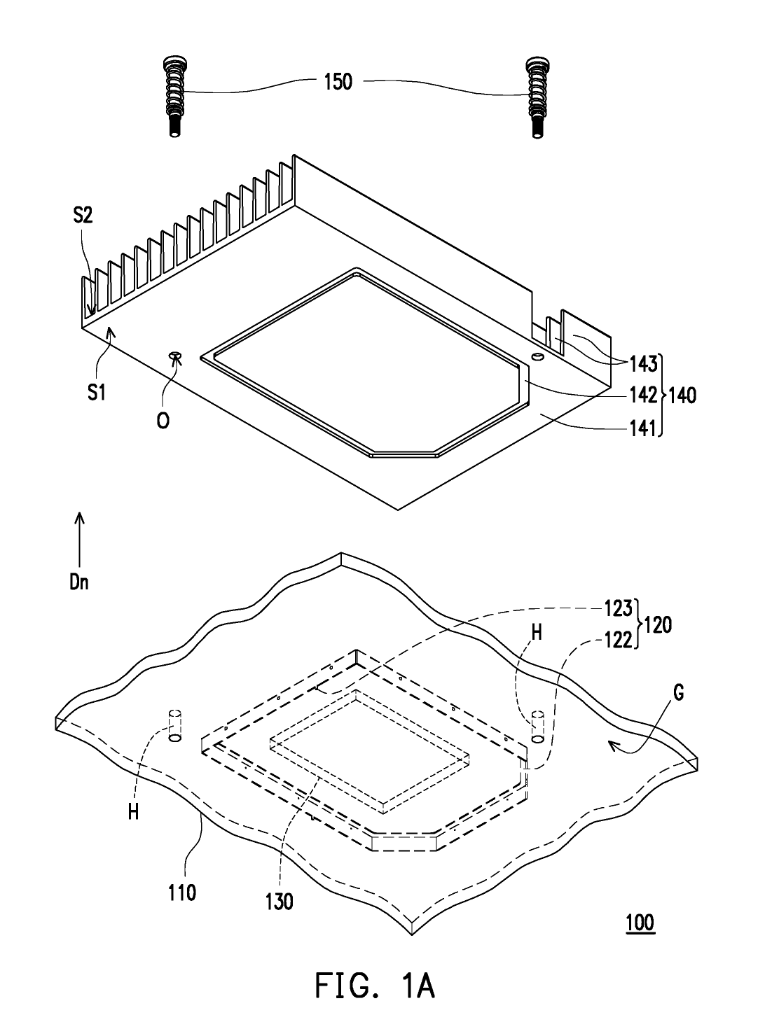

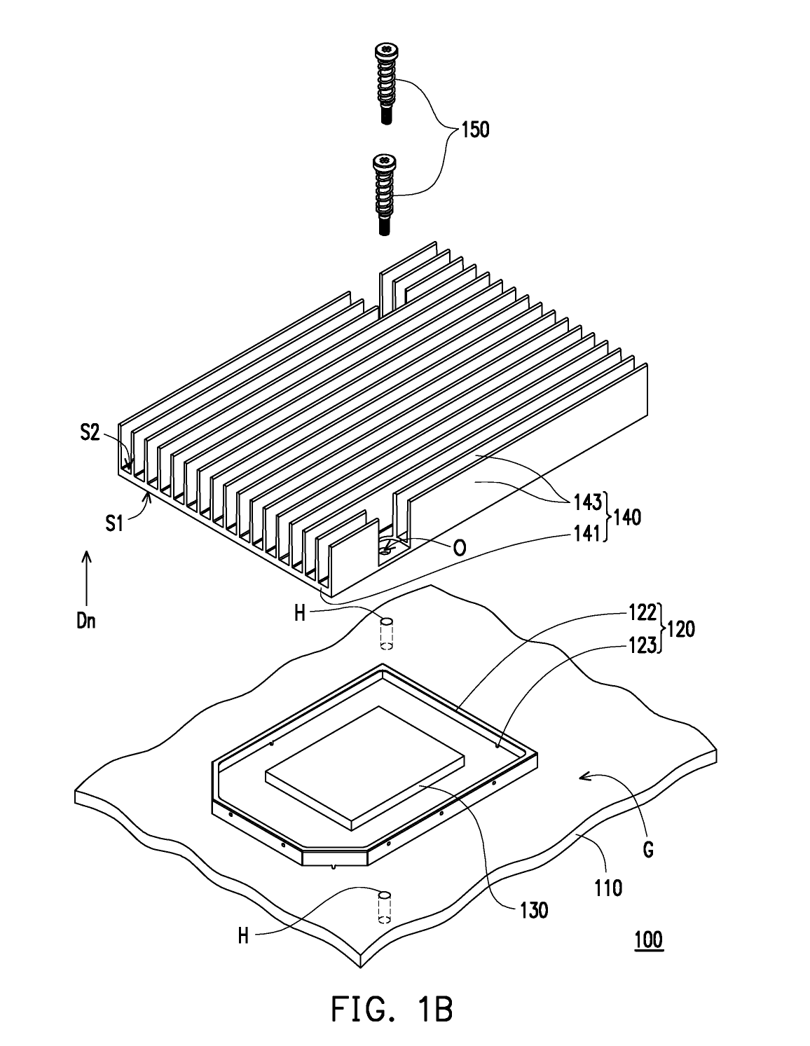

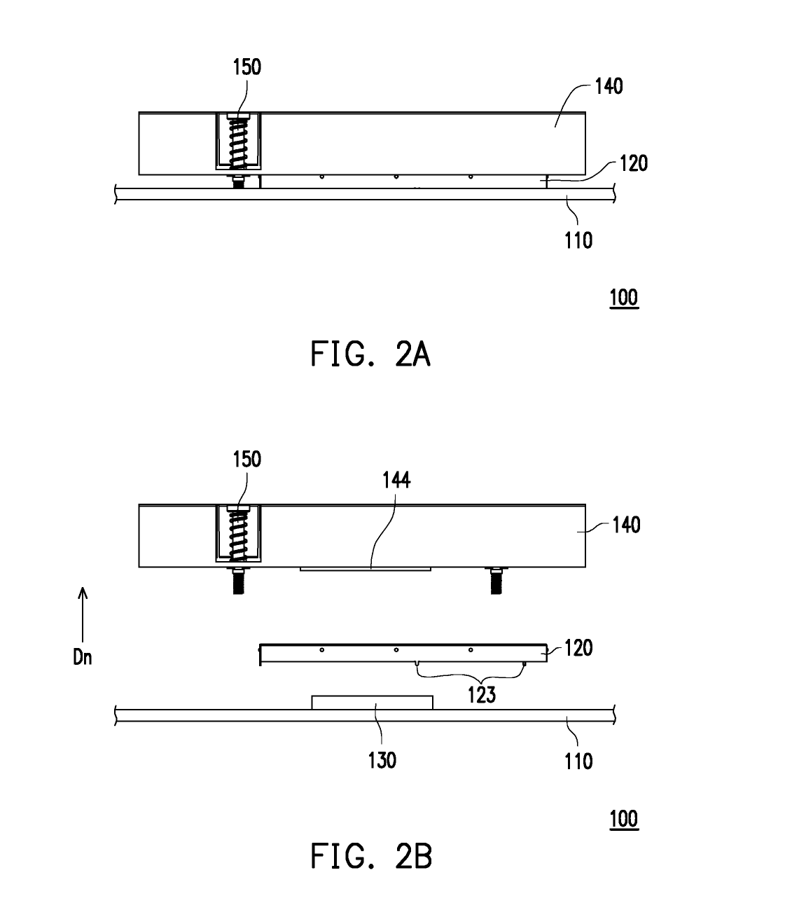

FIG. 1A is an exploded perspective view of a circuit board assembly according to an embodiment of the invention. FIG. 1B is another exploded perspective view of the circuit board assembly of FIG. 1A. FIG. 2A is an assembled side view of the circuit board assembly of FIG. 1A. FIG. 2B is an exploded side view of the circuit board assembly of FIG. 1A.

Referring to FIGS. 1A, 1B, 2A, and 2B, an embodiment of the circuit board assembly 100 includes a circuit board 110, a shielding frame 120, a chip 130, and a heat dissipating member 140. The circuit board 110 is, for example, a printed circuit board, and is adapted to be applied in all types of electronic devices. In this embodiment, the circuit board 110 can be configured as a computer motherboard or a mobile phone motherboard, but is not limited thereto. In other embodiments, the circuit board 110 may be a motherboard in any electronic device that has all electronic components disposed thereon.

The shielding frame 120 is, for example, a hollow frame body, and includes two openings. When the shielding frame 120 is fixed to the circuit board 110, the circuit board 110 covers one of the openings of the shielding frame 120, and the shielding frame 120 extends outwardly and protrude from the circuit board 110. The chip 130 is disposed on the circuit board 110 and is located in the shielding frame 120. In this embodiment, the chip 130 is, for example, a central processing unit (CPU) or other electronic components.

The heat dissipating member 140 is detachably disposed on the shielding frame 120 and is fixed to the circuit board 110. The heat dissipating member 140 covers the other opening of the shielding frame 120, and is adapted to contact the chip 130 in order to achieve heat conduction and dissipation. In this embodiment, when the shielding frame 120 and the heat dissipating member 140 are simultaneously disposed on the circuit board 110, such disposition are configured as a shielding device that is adapted to accommodate the chip 130 and prevent electromagnetic interference.

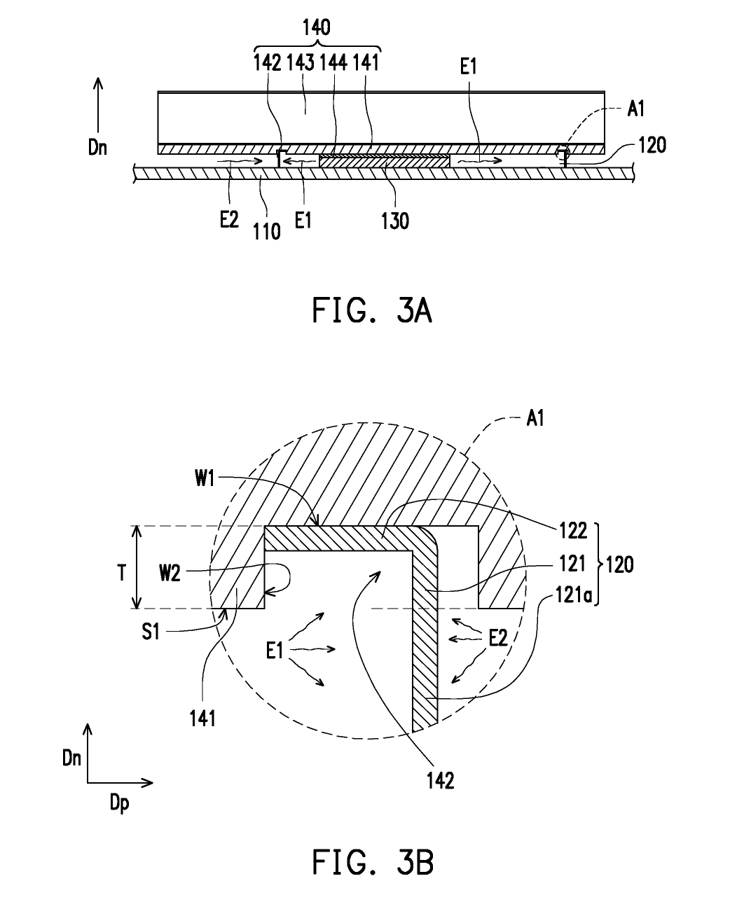

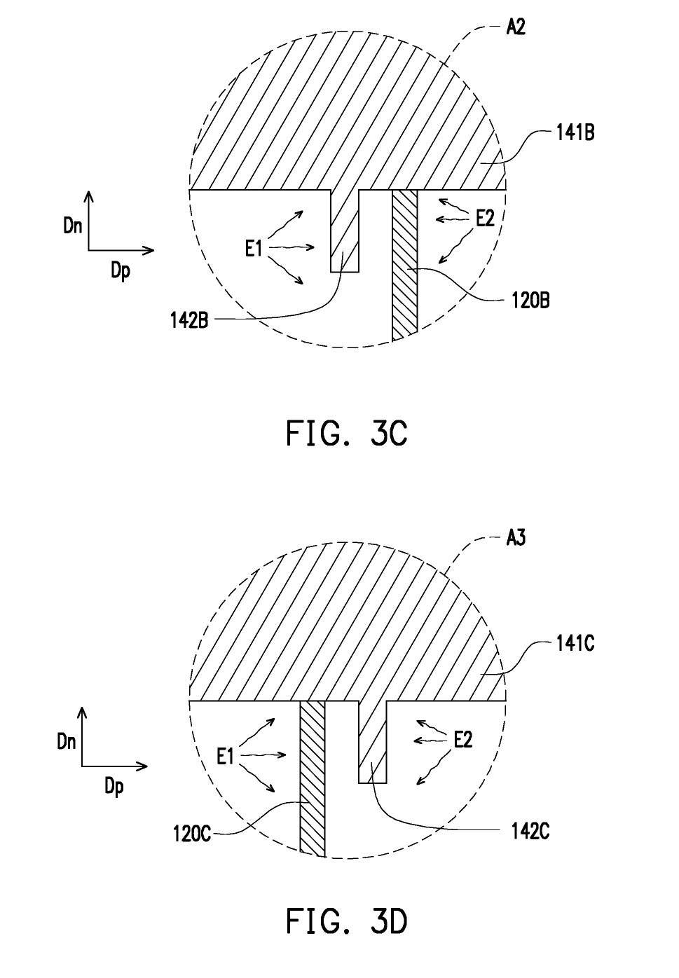

FIG. 3A is a sectional view of the circuit board assembly of FIG. 1A. FIG. 3B is a partial enlarged view of an area A1 in FIG. 3A.

Referring to FIGS. 3A and 3B, in this embodiment, the shielding frame 120 includes a first encircled positioning portion 121, an encircled abutting section 121a, and a bent section 122. The first encircled positioning portion 121 extends in a direction away from the circuit board 110. The encircled abutting section 121a is connected to the first encircled positioning portion 121, and extends to the circuit board 110 until it leans against the circuit board 110. The bent section 122 is formed on an inner edge of the first encircled positioning portion 121, and is spaced apart from the circuit board 110. The heat dissipating member 140 includes a plate 141 and a second encircled positioning portion 142. The plate 141 faces the circuit board 110. The second encircled positioning portion 142 is disposed on the plate 141. In this embodiment, the second encircled positioning portion 142 and the first positioning portion 141 correspond with each other in shape and position, so as to position the plate 141 and the shielding frame 120.

When the heat dissipating member 140 is disposed on the circuit board 110, the plate 141 leans against the bent section 122 of the shielding frame 120 and covers the chip 130, and one of the second encircled positioning portion 142 and the first encircled positioning portion 121 extends along a normal direction (Dn) of the plate 141 to the other one thereof, in order to allow the first encircled positioning portion 121 and the second encircled positioning portion 142 overlap each other in a horizontal direction (Dp) that is perpendicular to the normal direction (Dn).

Referring to FIGS. 3A and 3B, in this embodiment, the first encircled positioning portion 121 is, for example, an encircled protrusion. The second encircled positioning portion 142 is, for example, an encircled groove that corresponds to the encircled protrusion. The encircled protrusion and the encircled groove have corresponding polygonal shapes. The encircled protrusion may extend along the normal direction (Dn) into the encircled groove such that the encircled protrusion and the encircled groove have an overlapped area in the horizontal direction (Dp), and that the bent section 122 is in contact with a bottom wall (W1) and a side wall (W2) which is perpendicular to the bottom wall (W1) for mutually positioning. Specifically, the part of the shielding frame 120 extending into the second encircled positioning portion 142 or not protruding out of a first surface (S1) of the plate 141 is the first encircled positioning portion 121 (i.e., the encircled protrusion). The part of the shielding frame located out of the second encircled positioning portion 142 (i.e., the encircled groove) or protruding out of the first surface (S1) of the plate 141 is the encircled abutting section 121a.

In another embodiment, the first encircled positioning portion may be configured as an encircled groove formed on the shielding frame. The second encircled positioning portion may be configured as an encircled protrusion formed on the plate. When the heat dissipating member is disposed on the circuit board, the encircled groove may extend along the normal direction to accommodate the encircled protrusion, such that the encircled protrusion protrudes into the encircled groove, and that the shielding frame is in contact with the plate around the encircled protrusion for mutually positioning. The present invention is not limited thereto.

Referring to FIGS. 1A and 1B, the plate 141 has the first surface (S1) and a second surface (S2) opposite to the first surface (S1). The second encircled positioning portion 142 is located at the first surface (S1). The heat dissipating member 140 further includes a plurality of fins 143 and a heat dissipating pad 144. The fins 143 are located at the second surface (S2) and are spaced apart from each other. Air is capable of passing through a space between any adjacent two of the fins 143 so each of the fins 143 is adapted to dissipate heat of the plate 141 to environment, which is absorbed from the chip 130. The heat dissipating pad 144 (shown in FIGS. 2B and 3A) is disposed on the first surface (S1) of the plate 141, and is located at an inner side between the shielding frame 120 and the second positioning portion 142. The heat dissipating pad 144 has a surface contacting the chip 130, and such disposition improves thermal conductivity of the head dissipating member 140 relative to the chip 130. Referring to FIG. 3B, in this embodiment, the heat dissipating pad 144 is, for example, thermal grease or other heat-conductive materials. Specifically, the height difference (T) in the normal direction (Dn) exists between the bottom wall (W1) of the second encircled positioning portion 142 and the first surface (S1) of the plate 141.

Furthermore, referring to FIGS. 1A and 1B, the circuit board assembly 100 further includes a plurality of fixing members 150. The heat dissipating member 140 further has a plurality of through holes (O). The through holes (O) are through the first surface (S1) and the second surface (S2) of the plate 141 and are formed at a periphery of the second encircled positioning portion 142. The circuit board 110 has a plurality of securing holes (H) individually corresponding with the through holes (O), and a ground terminal (G). The fixing member 150 are, for example, screws, and individually pass through the through holes (O) and are fixed into the securing holes (H) of the circuit board 110. The ground terminal (G) is electrically connected to an inner surface of each of the securing holes (H). In this embodiment, the heat dissipating member 140 is made of, for example, metal, and is electrically connected to the ground terminal (G) of the circuit board 110 via the securing members 150. The shielding frame 120 is made of, for example, metal, and is mounted to the circuit board 110 by a welding process, and is electrically connected to the ground terminal (G). The plate 141 of the heat dissipating member 140 and the shielding frame 120 are electrically connected to each other so the plate 141 and the shielding frame 120 that surround the chip 130 can conduct static electricity to ground.

Referring to FIGS. 1A, 3A, and 3B, during the operation of the chip 130, electromagnetic radiation (E1) radiates from the center, the chip 130, toward the plate 141 and an inner side of the shielding frame 120. External electromagnetic radiation (E2) travels in another radiation direction toward an outer side of the shielding frame 120. The radiation directions of the electromagnetic radiation (E1, E2) are, for example, parallel to the horizontal direction (Dp), or form angles with the horizontal direction (Dp) Since part of the shielding frame 120 extends into the second encircled positioning portion 142 (i.e., the encircled groove) of the plate 141, the first encircled positioning portion 121 (i.e., the encircled protrusion) and the side wall (W2) of the second encircled positioning portion 142 (i.e., the encircled groove) overlap, and the bent section 122 abuts against the bottom wall (W1). The bottom wall (W1) of the second encircled positioning portion 142 and the first surface (S1) of the plate 141 have a height difference (T) in the normal direction (Dn) in between. The electromagnetic radiation (E1, E2) propagates in Light of Sight (LOS). During the propagation, since the electromagnetic radiation (E1) cannot turn 90 degrees to enter the second encircled positioning portion 142 (i.e., the encircled groove) of the plate 141 in the normal direction (Dn), and cannot turn 90 degrees to pass through the bottom wall (W1) and the bent section 122 in the horizontal direction (Dp), the electromagnetic radiation (E1) propagating outwardly from the chip 130 is blocked by the plate 141 and the shielding frame 140. In other embodiments, a gap of a certain dimension may exist between the bottom wall (W1) and the bent section 122. Since the transmission of the electromagnetic radiation (E1) is limited to be LOS propagation, the electromagnetic radiation (E1) cannot turn twice to pass through the gap.

In addition, when the electromagnetic radiation (E1) contacts the plate 141 and the shielding frame 120, it is guided to the ground terminal (G) of the circuit board 110, in order to prevent outward emission of the electromagnetic radiation (E1). Similarly, when the external electromagnetic radiation (E2) travels toward the chips 130 along the plate 141 and the circuit board 110, the electromagnetic radiation (E2) cannot turn 90 degrees to enter the second encircled positioning portion 142 (i.e., the encircled groove) of the plate 141 in the normal direction (Dn), and cannot turn 90 degrees to pass through the bottom wall (W1) and the bent section 122 in the direction opposite to the horizontal direction (Dp). The electromagnetic radiation (E2) is blocked by the plate 141 and the shielding frame 120. When the electromagnetic radiation (E2) contacts the plate 141 and the shielding frame 120, it is guided to the ground terminal (G) of the circuit board 110, in order to prevent the electromagnetic radiation (E2) from affecting the operation of the chip 130. Therefore, the shielding frame 120 can prevent the chip 130 from negative affect caused by electromagnetic interference.

Referring to FIGS. 1A and 1B, in this embodiment, the shielding frame 120 further includes a plurality of locking portions 123 formed on a surface of the shielding frame 120, which faces the circuit board 110. The locking portions 123 are, for example, spaced-apart bumps fixed to the circuit board 110, so as to allow the shielding frame 120 to be connected to the circuit board 110 via welding. Hence, the shielding frame 120 is electrically connected to the ground terminal (G) of the circuit board 110 via welding.

FIGS. 3C and 3D are partial enlarged views of areas A2 and A3, respectively, which replace the area A1 in other embodiments. Other embodiments according to the present invention would be described as follows. It should be noted that, in the following description, components identified with numerals similar to the previous embodiment are omitted for the brevity, only those different from the previous embodiment would be disclosed in detail.

Referring to FIGS. 3A, 3C and 3D, the areas (A2) in FIG. 3C and the area (A3) in FIG. 3D can replace the area (A1) in FIG. 3A. In other embodiments, when the heat dissipating member 140 is disposed on the circuit board 110, the shielding frame 120B, 120C leans against the heat dissipating member 140 in the normal direction (Dn), and the heat dissipating member 140 covers the chip 130. The shielding frame 120B, 120C overlap the heat dissipating member 140 at a junction in the radiation direction (i.e., a direction in which the electromagnetic radiation (E1) radiates from the center, the chip 130. The radiation direction is, for example, parallel to the horizontal direction (Dp) or form an angle with the horizontal direction (Dp). Specifically, referring to FIGS. 3C and 3D, the plate 141B, 141C has a second encircled positioning portion 142B, 142C, which is an encircled protrusion extending from the plate 141B, 141C. When the plate 141B, 141C leans against the shielding frame 120B, 120C, the second encircled positioning portion 142B, 142C is, for example, located at an inner side or an outer side of the shielding frame 120B, 120C, such that the encircled protrusion and the shielding frame 120B, 120C have an overlapped area in the horizontal direction (Dp). Since the height difference exists between the gap of the shielding frame 120B, 120C and the plate 141B, 141C and the encircled protrusion, the electromagnetic radiation (E1) and the electromagnetic radiation (E2) cannot turn and pass through the shielding frame 120B, 120C and the encircled protrusion, and thus the electromagnetic interference is avoided.

In summary, the circuit board assembly according to the present invention is equipped with detachable shielding device, which is different from a conventional cover molded as one piece. When the heat dissipating member is disposed on the circuit board, the heat dissipating member and the shielding frame are used for preventing electromagnetic interference from affecting the chip. The shielding frame is designed to be hollow and coupled to the plate of the heat dissipating member for covering the chip, and the shielding frame and the plate overlap each other and form the gap with the height difference, so that the electromagnetic radiation cannot pass through and is blocked by the shielding frame and the plate. Moreover, the shielding frame and the plate can guide the electromagnetic radiation to the ground terminal, and thus electromagnetic interference affecting the operation of the chip is prevented.

In addition, the circuit board assembly of the present invention adopts the shielding device, which includes the heat dissipating member and the shielding frame and also takes the plate of the heat dissipating member as the upper cover of the shielding frame. That is, the shielding frame of the present invention is not required to be equipped with an additional upper cover, therefore, the size (i.e., thickness) of the shielding device is reduced, and the production cost is also reduced. To be specific, due to the reduced size, the circuit board assembly of the present invention can be adapted to a relatively small electronic device.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A circuit board assembly, comprising:
a circuit board;
a shielding frame, fixed to and protruding from the circuit board, the shielding frame comprising a first encircled positioning portion that is away from the circuit board;
a chip, disposed on the circuit board and located in the shielding frame; and
a heat dissipating member, detachably disposed on the shielding frame, and comprising a plate and a second encircled positioning portion that is disposed on the plate, wherein when the heat dissipating member is disposed on the circuit board, the plate leans against the shielding frame and covers the chip, the second encircled positioning portion and the first encircled positioning portion correspond with each other in shape and position, so as to position the plate and the shielding frame.

2. The circuit board assembly as claimed in claim 1, wherein the second encircled positioning portion is an encircled groove, the first encircled positioning portion is an encircled protrusion that corresponds to the encircled groove.

3. The circuit board assembly as claimed in claim 2, wherein the first encircled positioning portion has a bent section in contact with a bottom wall of the encircled groove.

4. The circuit board assembly as claimed in claim 1, wherein the shielding frame is electrically connected to a ground terminal of the circuit board.

5. The circuit board assembly as claimed in claim 1, further comprising a plurality of fixing members, the heat dissipating member further comprising a plurality of through holes that are formed at a surrounding of the second encircled positioning portion, wherein the fixing members individually pass through the through holes, and are fixed to the circuit board and electrically connected to a ground terminal of the circuit board.

6. A circuit board assembly, comprising:
a circuit board;
a shielding frame, fixed to and protruding from the circuit board;
a chip, disposed on the circuit board and located in the shielding frame; and
a heat dissipating member, detachably disposed on the shielding frame,
wherein when the heat dissipating member is disposed on the circuit board, the heat dissipating member leans against the shielding frame and covers the chip, and the shielding frame overlaps the heat dissipating member at a junction in a radiation direction from a center of the chip.

7. A shielding device, adapted to be disposed on a circuit board and cover a chip that is disposed on the circuit board, the shielding device comprising:
a shielding frame, comprising a first encircled positioning portion; and
a heat dissipating member, comprising a plate and a second encircled positioning portion that is disposed on the plate, wherein the second encircled positioning portion and the first encircled positioning portion correspond with each other in shape and position, so as to position the plate and the shielding frame,
when the shielding device is disposed on the circuit board, an encircled abutting section of the shielding frame connected to the first encircled positioning portion leans against the circuit board, and the shielding frame and the heat dissipating member cooperatively cover the chip.

8. The shielding device as claimed in claim 7, wherein the second encircled positioning portion is an encircled groove, the first encircled positioning portion is an encircled protrusion that corresponds to the encircled groove.

9. The shielding device as claimed in claim 7, wherein the first encircled positioning portion has a bent section in contact with a bottom wall of the encircled groove.

10. The shielding device as claimed in claim 7, wherein the plate has a first surface and a second surface opposite the first surface, the second encircled positioning portion is located at the first surface, the heat dissipating member further comprise a plurality of fins located at the second surface.
